(19) United States
(12) Patent Application Publication
(10) Pub. No.: US 2016/0005816 A1
(43) Pub. Date: Jan. 7, 2016

(54) Group III-V Transistor with Voltage Controlled Substrate

(71) Applicant: International Rectifier Corporation, El Segundo, CA (US)

(72) Inventors: Hyeongnam Kim, Chandler, AZ (US); Mohamed Imam, Chandler, AZ (US); Deepak Veereddy, Chandler, AZ (US)

(73) Assignee: International Rectifier Corporation

(21) Appl. No.: 14/733,426

(22) Filed: Jun. 8, 2015

Related U.S. Application Data
(60) Provisional application No. 62/020,277, filed on Jul. 2, 2014.

(51) Int. Cl. H01L 29/10; H01L 29/20; H01L 29/778

(52) U.S. Cl. CPC H01L 29/107; H01L 29/778; H01L 29/2003

(57) ABSTRACT

There are disclosed herein various implementations of a group III-V transistor with a voltage controlled substrate. A semiconductor structure providing such a group III-V transistor includes a group IV substrate having a dielectrically-filled region, and a group III-V body situated over a top surface of the group IV substrate. The group III-V body includes a group III-V transistor having a top drain electrode, a top gate electrode, and a top source electrode. The semiconductor structure also includes a source-side via extending through the group III-V body to couple the top source electrode to a source-side region of the group IV substrate so as to reduce an R_{dson} of the group III-V transistor, and also to increase a breakdown voltage of the group III-V transistor.

The present application claims the benefit of and priority to a provisional application entitled “III-Nitride-on-Silicon Devices with Dielectrically Filled Patterned Regions of the Silicon Substrate,” Ser. No. 62/020,277 filed on Jul. 2, 2014. The disclosure in this provisional application is hereby incorporated fully by reference into the present application.

### BACKGROUND

I. Definition

As used herein, the phrase “group III-V” refers to a compound semiconductor including at least one group III element and at least one group V element. By way of example, a group III-V semiconductor may take the form of a III-Nitride semiconductor. “III-Nitride” or “III-N” refers to a compound semiconductor that includes nitrogen and at least one group III element such as aluminum (Al), gallium (Ga), indium (In), and boron (B), and including but not limited to any of its alloys, such as aluminum gallium nitride (AlₓGa₍₁₋ₓ₎N), indium gallium nitride (In_{y}Ga_{(1-y)}N), aluminum indium gallium nitride (AlₓIn_{y}Ga_{(1-x-y)}N), gallium arsenide phosphide nitride (GaAsₐP_{b}N_{(1-a-b)}), aluminum indium gallium arsenide phosphide nitride (AlₓIn_{y}Ga_{(1-x-y)}AsₐP_{b}N_{1-a-b)}), for example. III-N also refers generally to any polarity including but not limited to Ga-polar, N-polar, semi-polar, or non-polar crystal orientations. A III-N material may also include either the Wurtzitic, Zincblende, or mixed polytypes, and may include single-crystal, monocrystalline, polycrystalline, or amorphous structures. Gallium nitride or GaN, as used herein, refers to a III-N compound semiconductor wherein the group III element or elements include some or a substantial amount of gallium, but may also include other group III elements in addition to gallium.

In addition, as used herein, the phrase “group IV” refers to a semiconductor that includes at least one group IV element such as silicon (Si), germanium (Ge), and carbon (C), and may also include compound semiconductors such as silicon germanium (SiGe) and silicon carbide (SiC), for example. Group IV also refers to semiconductor materials which include more than one layer of group IV elements, or doping of group IV elements to produce strained group IV materials, and may also include group IV based composite substrates such as single-crystal or polycrystalline SiC on silicon, silicon on insulator (SOI), separation by implantation of oxygen (SIMOX) process substrates, and silicon on sapphire (SOS), for example.

It is noted that, as used herein, the terms “low voltage” or “LV” in reference to a transistor or switch describes a transistor or switch with a voltage range of up to approximately fifty volts (50V). It is further noted that use of the term “midvoltage” or “MV” refers to a voltage range from approximately fifty volts to approximately two hundred volts (approximately 50V to 200V). Moreover, the term “high voltage” or “HV,” as used herein, refers to a voltage range from approximately two hundred volts to approximately twelve hundred volts (approximately 200V to 1,200V), or higher.

II. Background Art

In high power and high performance circuit applications, group III-V field-effect transistors (FETs), such as gallium nitride (GaN) or other III-Nitride based high mobility electron transistors (HEMTs), are often desirable for their high efficiency and high voltage operation. III-Nitride and other group III-V HEMTs operate using polarization fields to generate a two-dimensional electron gas (2-DEG) allowing for high current densities with low resistive losses.

Although their high breakdown voltage, high current density, and low on-resistance (R_{dson}) render group III-V HEMTs potentially advantageous for use in power applications, III-Nitride and other group III-V HEMTs may be susceptible to the effects of current leakage. For example, the structures providing such group III-V devices typically include pathways for current flow and leakage that can adversely affect the performance of the devices by reducing breakdown voltage or causing R_{dson} to increase during switching.

### SUMMARY

The present disclosure is directed to a group III-V transistor with voltage controlled substrate, substantially as shown in and/or described in connection with at least one of the figures, and as set forth in the claims.

### BRIEF DESCRIPTION OF THE DRAWINGS

FIG. 1A shows a cross-sectional view of an exemplary group III-V transistor with a substrate having a dielectrically-filled region, according to one implementation.

FIG. 1B shows a cross-sectional view of an exemplary group III-V transistor with a substrate having a dielectrically-filled region, according to another implementation.

FIG. 2 shows a cross-sectional view of an exemplary group III-V transistor with a voltage controlled substrate having a dielectrically-filled region, according to one implementation.

FIG. 3 shows a cross-sectional view of an exemplary group III-V transistor with a voltage controlled substrate having a dielectrically-filled region, configured as a lateral high electron mobility transistor (HEMT) having backside contacts, according to one implementation.

FIG. 4A shows a cross-sectional view of an exemplary group III-V transistor with a voltage controlled substrate having a dielectrically-filled region, configured as a lateral HEMT having a backside contact, according to another implementation.

FIG. 4B shows a cross-sectional view of an exemplary group III-V transistor with a voltage controlled substrate having a dielectrically-filled region, configured as a lateral HEMT having a backside contact, according to yet another implementation.

FIG. 5A shows a cross-sectional view of an exemplary group III-V transistor with a substrate having a dielectrically-filled region and a voltage controlled source-side region, configured as a lateral HEMT having a backside contact, according to one implementation.

FIG. 5B shows a cross-sectional view of an exemplary group III-V transistor with a substrate having a dielectrically-filled region and a voltage controlled source-side region, configured as a lateral HEMT having a backside contact, according to another implementation.

### DETAILED DESCRIPTION

The following description contains specific information pertaining to implementations in the present disclosure. One skilled in the art will recognize that the present disclosure may be implemented in a manner different from that specifically discussed herein. The drawings in the present application and their accompanying detailed description are directed to merely exemplary implementations. Unless noted otherwise, like or corresponding elements among the figures may be indicated by like or corresponding reference numerals. Moreover, the drawings and illustrations in the present application are generally not to scale, and are not intended to correspond to actual relative dimensions.

As noted above, despite their many desirable performance characteristics, including high breakdown voltage, high current density, and low on-resistance (R_{dson}), III-Nitride and other group III-V high electron mobility transistors (HEMTs) are susceptible to performance degradation due to the presence of leakage pathways in the device structure. For example, leakage pathways may be present between the active layers of such a transistor and its substrate, across the substrate surface, and within the substrate itself (particularly if the substrate is highly doped so as to be conductive). The presence of these leakage pathways can negatively affect transistor performance in a number of ways. For instance, leakage pathways within a HEMT structure can reduce the standoff voltage performance of the HEMT, i.e., by reducing its breakdown voltage, as well as increase capacitive coupling of the HEMT to the substrate, thereby undesirably increasing R_{dson} during switching.

The present application discloses a group III-V transistor, such as a III-Nitride or other group III-V HEMT, with a voltage controlled substrate having a dielectrically-filled region and configured to reduce or substantially eliminate leakage within the structure providing the transistor. In addition, according to the implementations disclosed in the present application, the group III-V transistor is situated substantially over the dielectrically-filled region. As a result, breakdown voltage of such a group III-V transistor is increased, while capacitive coupling of the transistor to its substrate is reduced, resulting in a reduction of R_{dson} during switching.

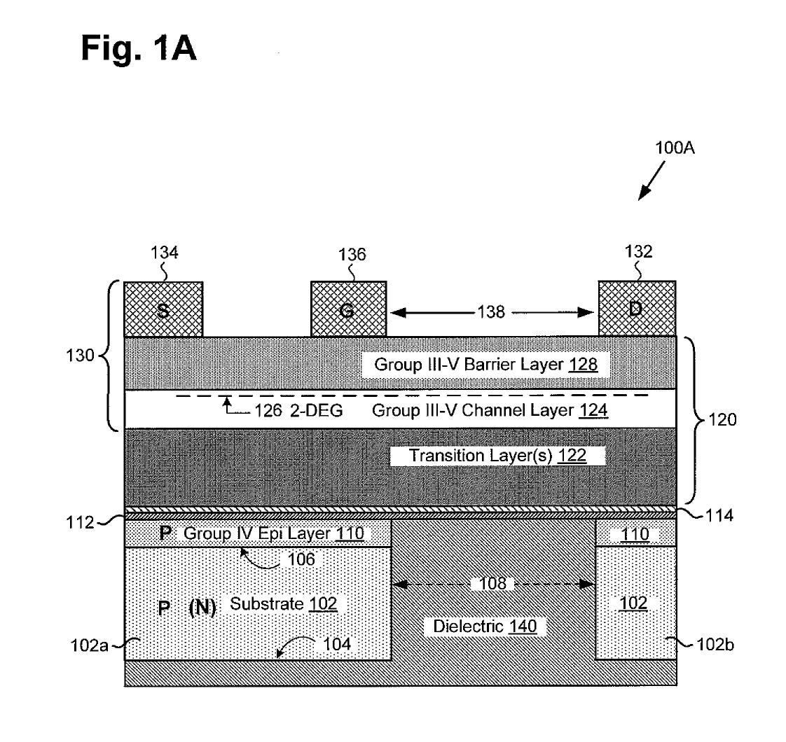

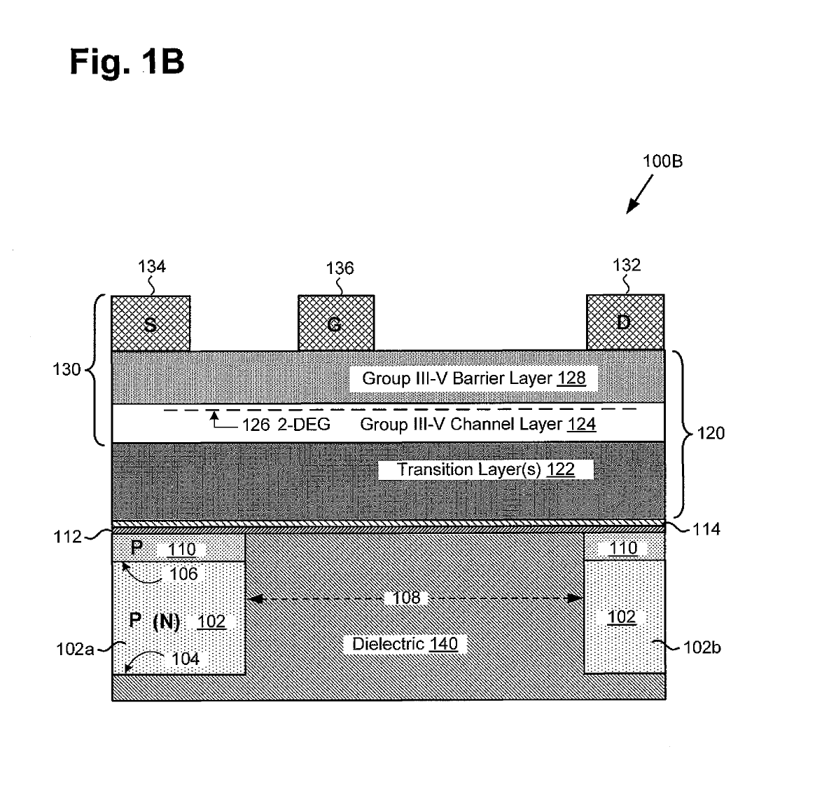

FIG. 1A shows a cross-sectional view of semiconductor structure 100A including a group III-V transistor utilizing a substrate having a dielectrically-filled region, according to one implementation. According to the exemplary implementation shown in FIG. 1A, semiconductor structure 100A includes group III-V body 120 situated over top surface 106 of substrate 102. As shown in FIG. 1A, substrate 102 includes source-side substrate region 102a, drain-side substrate region 102b, and dielectrically-filled region 108, and, in addition to top surface 106, has bottom surface 104.

As further shown in FIG. 1A, group III-V body 120 includes group III-V transistor 130 having top drain electrode 132, top source electrode 134, and top gate electrode 136. Also shown in FIG. 1A is distance 138 separating top drain electrode 132 from top gate electrode 136 and corresponding to a drift region of group III-V transistor 130. In addition, FIG. 1A shows optional group IV epitaxial layer 110, strain-absorbing layer 112, and nucleation layer 114, all situated between top surface 106 of substrate 102 and group III-V body 120.

According to the exemplary implementation shown in FIG. 1A, group III-V transistor 130 may be implemented as a lateral III-Nitride or other group III-V HEMT. Group III-V transistor 130 may take the form of a lateral gallium nitride (GaN) based HEMT, for example, configured to produce 2-DEG 126. According to one implementation, group III-V transistor 130 may be a high voltage (HV) device, as described above in the “Definition” section. For instance, group III-V transistor 130 may be configured to sustain a drain voltage of approximately six hundred volts (600V) and to have a gate rating of approximately 40V.

It is noted that although FIG. 1A represents group III-V transistor 130 as a HEMT, in other implementations, group III-V transistor 130 may take other forms. For example, in some implementations, group III-V transistor 130 may take the form of a lateral group III-V metal-insulator-semiconductor field-effect transistor (MISFET), such as an HV group III-V metal-oxide-semiconductor FET (MOSFET).

As shown in FIG. 1A, substrate 102 may be a P type or N type substrate having top surface 106 and bottom surface 104 opposite top surface 106. Substrate 102 may be a group IV substrate, such as a silicon substrate, for example, as described in greater detail above in the “Definition” section. Moreover, in some implementations, substrate 102 may be a highly doped P type or N type substrate, resulting in substrate 102 being an electrically conductive substrate.

Substrate 102 is shown to have been patterned to form source-side substrate region 102a and drain-side substrate region 102b separated by a gap that has been substantially filled with dielectric material 140 to form dielectrically-filled region 108. Dielectric material 140 may be a low-k dielectric material having a dielectric constant less than the dielectric constant of silicon dioxide (SiO₂), i.e., a dielectric constant less than approximately 3.9. For example, dielectric material 140 may include carbon doped or fluorine doped SiO₂, or carbon or fluorine doped silicon nitride (Si₃N₄), among other suitable low-k dielectric materials. Moreover, and as further shown in FIG. 1A, in some implementations, dielectric material 140 filling dielectrically-filled region 108 may extend under bottom surface 104 of substrate 102 so as to substantially cover bottom surface 104 of source-side substrate region 102a and/or drain-side substrate region 102b.

Group III-V body 120 including group III-V transistor 130 includes transition layer or layers 122, group III-V channel layer 124, and group III-V barrier layer 128, all situated over top surface 106 of substrate 102. Transition layer(s) 122 may include multiple group III-V layers, for example. It is noted that transition layer(s) 122 is/are provided to mediate the transition in lattice properties from substrate 102 to group III-V channel layer 124 and group III-V barrier layer 128.

In implementations in which group III-V body 120 takes the form of a III-Nitride body, for example, transition layer(s) 122 may include a series of III-Nitride material layers, such as AlGaN layers having a progressively reduced aluminum content relative to their gallium content, until a suitable transition to a GaN buffer layer included in transition layer(s) 122 is achieved. Moreover, in some implementations, transition layer(s) 122 may take the form of one or more compositionally graded layers having different group III-V alloy compositions at respective top and bottom surfaces. It is noted that the specific compositions and thicknesses of transition layer(s) 122 may depend on the diameter and thickness of substrate 102, and the desired performance of group III-V transistor 130.

As shown in FIG. 1A, group III-V channel layer 124 is formed over transition layer(s) 122, and group III-V barrier layer 128 is formed over group III-V channel layer 124. As further shown in FIG. 1A, group III-V channel layer 124 and group III-V barrier layer 128 are configured to produce 2-DEG 126 near their heterostructure interface. In one implementation, for example, group III-V transistor 130 may take the form of a III-Nitride HEMT having a GaN layer as group III-V channel layer 124 and an AlGaN layer as group III-V barrier layer 128.

According to one implementation, semiconductor structure 100A may also include strain-absorbing layer 112 formed over top surface 106 of substrate 102 so as to further reduce the net mismatch in thermal coefficient of expansion between substrate 102 and later formed group III-V active layers, such as group III-V channel layer 124 and group III-V barrier layer 128. Strain-absorbing layer 112 may be an amorphous strain-absorbing layer, such as, for example, an amorphous silicon nitride layer. In addition, in some implementations, semiconductor structure 100A may include nucleation layer 114 in addition to, or in lieu of, strain-absorbing layer 112. For instance, when forming a GaN based HEMT as group III-V transistor 130, nucleation layer 114 may be an aluminum nitride (AlN) layer formed over top surface 106 of substrate 102.

In some implementations, as shown in FIG. 1A, it may be advantageous or desirable for semiconductor structure 100A to further include group IV epitaxial layer 110 between top surface 106 of substrate 102 and group III-V body 120. Group IV epitaxial layer 110 may be an epitaxial silicon or silicon based layer, for example, and in some implementations may be epitaxially grown on top surface 106 of substrate 102. Group IV epitaxial layer 110, may be formed as a P type epitaxial group IV layer, and in some implementations may be highly doped so as to function, in effect, as a conductive silicon or other group IV layer.

It is noted that in implementations in which semiconductor structure 100A includes group IV epitaxial layer 110, group IV epitaxial layer 110, like substrate 102, may be patterned to include a gap that is substantially filled with dielectric material 140. That is to say, in some implementations, dielectrically-filled region 108 may extend through group IV epitaxial layer 110, as well as through substrate 102, as shown in FIG. 1A.

As further shown in FIG. 1A, group III-V transistor 130 is situated substantially over dielectrically-filled region 108. For example, and according to the specific implementation of FIG. 1A, group III-V transistor 130 may be situated so as to have its drift region corresponding to distance 138 situated substantially over dielectrically-filled region 108. In other words, in some implementations, dielectrically-filled region 108 of substrate 102 extends under group III-V body 120 between top drain electrode 132 and top gate electrode 136 for a distance less than or substantially equal to distance 138. As a result, the exemplary implementation shown in FIG. 1A can reduce or substantially eliminate leakage under the drift region of group III-V transistor 130 corresponding to distance 138. Consequently, the standoff voltage performance of group III-V transistor 130 is improved, while capacitive coupling of group III-V transistor 130 to substrate 102 is reduced.

Thus, group III-V transistor 130 being situated substantially over dielectrically-filled region 108 of substrate 102 results in group III-V transistor 130 having an increased breakdown voltage and a reduced R_{dson} compared to conventional transistors utilizing substrates that omit dielectrically-filled region 108.

Moving to FIG. 1B, FIG. 1B shows a cross-sectional view of semiconductor structure 100B including a group III-V transistor utilizing a substrate having a dielectrically-filled region, according to another implementation. Semiconductor structure 100B includes group III-V body 120 having transition layer(s) 122, group III-V channel layer 124, and group III-V barrier layer 128, all situated over top surface 106 of substrate 102. As shown in FIG. 1B, group III-V body 120 includes group III-V transistor 130 having top drain electrode 132, top source electrode 134, top gate electrode 136, and configured to produce 2-DEG 126.

As further shown in FIG. 1B, in addition to top surface 106, substrate 102 also includes bottom surface 104, source-side substrate region 102a, drain-side substrate region 102b, and dielectrically-filled region 108 substantially filled by dielectric material 140. Also shown in FIG. 1B are optional group IV epitaxial layer 110, strain-absorbing layer 112, and nucleation layer 114.

Substrate 102, dielectric material 140, group III-V body 120, and group III-V transistor 130 correspond respectively to the features identified by reference numbers 102, 140, 120, and 130, in FIG. 1A, and may share any of the characteristics attributed to those features, above. In addition, group IV epitaxial layer 110, strain-absorbing layer 112, and nucleation layer 114, in FIG. 1B, correspond respectively to the features identified by reference numbers 110, 112, and 114, in FIG. 1A, and may share any of the characteristics attributed to those features, above.

It is noted that, in contrast to the implementation shown in FIG. 1A, dielectrically-filled region 108, in semiconductor structure 100B, extends beyond the drift region of group III-V transistor 130 corresponding to distance 138 in FIG. 1A. For example, and as shown in FIG. 1B, in some implementations, dielectrically-filled region 108 extends from top drain electrode 132, under top gate electrode 136, to approach top source electrode 134. That is to say, in some implementations, dielectrically-filled region 108 extends under group III-V body 120 between top drain electrode 132 and top source electrode 134. As a result, exemplary semiconductor structure 100B, in FIG. 1B, can reduce or substantially eliminate leakage in group III-V transistor 130. Consequently, the standoff voltage performance of group III-V transistor 130 is further improved, while capacitive coupling of group III-V transistor 130 to substrate 102 is further reduced.

Thus, like the implementation shown in FIG. 1A, semiconductor structure 100B, in FIG. 1B, in which group III-V transistor 130 is situated substantially over dielectrically-filled region 108, results in group III-V transistor 130 having an increased breakdown voltage and a reduced R_{dson} compared to conventional transistors utilizing substrates that omit dielectrically-filled region 108.

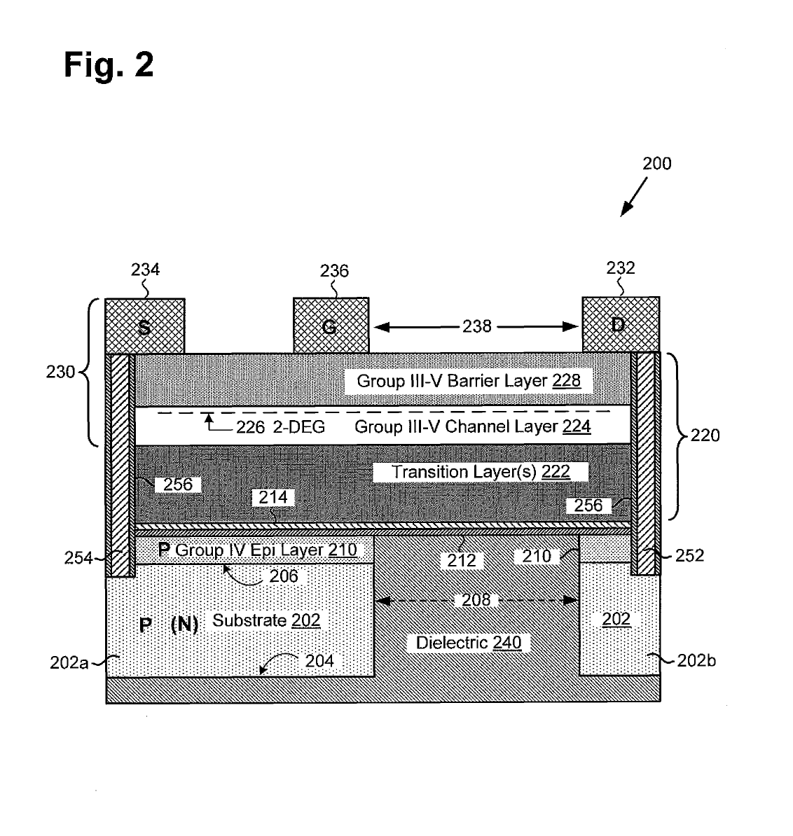

Referring to FIG. 2, FIG. 2 shows a cross-sectional view of semiconductor structure 200 including an exemplary group III-V transistor with a voltage controlled substrate having a dielectrically-filled region, according to one implementation. Semiconductor structure 200 includes group III-V body 220 having transition layer(s) 222, group III-V channel layer 224, and group III-V barrier layer 228, all situated over top surface 206 of substrate 202. As shown in FIG. 2, group III-V body 220 includes group III-V transistor 230 having top drain electrode 232, top source electrode 234, top gate electrode 236, and configured to produce 2-DEG 226.

As further shown in FIG. 2, in addition to top surface 206, substrate 202 also includes bottom surface 204, source-side substrate region 202a, drain-side substrate region 202b, and dielectrically-filled region 208 substantially filled by dielectric material 240. Also shown in FIG. 2 are distance 238 and source-side via 254 lined by insulator 256, as well as optional drain-side via 252 lined by insulator 256, group IV epitaxial layer 210, strain-absorbing layer 212, and nucleation layer 214.

Substrate 202, dielectric material 240, group III-V body 220, and group III-V transistor 230 correspond respectively to substrate 102, dielectric material 140, group III-V body 120, and group III-V transistor 130, in FIGS. 1A and 1B, and may share any of the characteristics attributed to those corresponding features, above. That is to say, substrate 202 may be a highly doped silicon or other group IV substrate including dielectrically-filled region 208, dielectric material 240 may be a low-k dielectric material, and group III-V transistor 230 may take the form of a III-Nitride transistor, such as a III-Nitride or other group III-V HEMT.

In addition, group IV epitaxial layer 210, strain-absorbing layer 212, and nucleation layer 214, in FIG. 2, correspond respectively to group IV epitaxial layer 110, strain-absorbing layer 112, and nucleation layer 114, in FIGS. 1A and 1B, and may share any of the characteristics attributed to those corresponding features, above. Moreover, distance 238, in FIG. 2, corresponds to distance 138 in FIG. 1A, and may share any of the characteristics attributed to that corresponding feature, above.

It is noted that, in contrast to the implementations shown in FIGS. 1A and 1B, semiconductor structure 200, in FIG. 2, includes source-side via 254, and may further include optional drain-side via 252. Source-side via 254 and drain side via 252 are conductive through-semiconductor vias extending through group III-V body 220 to couple respective top source electrode 234 and top drain electrode 232 to respective source-side substrate region 202a and drain-side substrate region 202b. Moreover, and as shown by FIG. 2, source-side via 254 and drain-side via 252 are lined by insulator 256 to electrically isolate source-side via 254 and drain side via 252 from group III-V body 220. Source-side via 254 and drain-side via 252 may include any suitable electrically conductive material, such as a metal filler, for example. Insulator 256 lining source-side via 254 and drain-side via 252 may be any suitable dielectric material, such as a deposited or thermally grown SiO₂, for example.

It is further noted that although FIG. 2 shows source-side via 254 and drain-side via 252 terminating in substrate 202, in implementations in which group IV epitaxial layer 210 is present as a highly doped and therefore conductive layer, source-side via 254 and/or drain-side via 252 may terminate in group IV epitaxial layer 210. In those implementations, source-side via 254 couples top source electrode 234 to source-side substrate region 202a through group IV epitaxial layer 210, while drain-side via 252 can couple top drain electrode 232 to drain-side substrate region 202b through group IV epitaxial layer 210.

The presence of source-side via 254 and/or drain-side via 252 in semiconductor structure 200 results in substrate 202 being a voltage controlled substrate. For example, by coupling top source electrode 234 to source-side substrate region 202a, source-side via 254 ties source-side substrate region 202a to the potential of top source electrode 234. As a result, electric fields that would otherwise be present if source-side substrate region 202a were permitted to float are instead reduced or eliminated. Consequently, source-side via 254 extending through group III-V body 220 to couple top source electrode 234 to source-side substrate region 202a reduces the R_{dson} of group III-V transistor 230.

With respect to drain-side via 252, by coupling top drain electrode 232 to drain-side substrate region 202b, drain-side via 252 ties drain-side substrate region 202b to the potential of top drain electrode 232. As a result, electric fields that would otherwise be present due to the typically large potential difference between drain-side substrate region 202b and top drain electrode 232 are reduced or eliminated due to drain-side via 252, substantially reducing the likelihood voltage breakdown in the drift region of group III-V transistor. Consequently, the drift region of group III-V transistor 230 may advantageously be made significantly longer than is possible in conventional semiconductor structures. For example, distance 238 between top drain electrode 232 and top gate electrode 236 may be extended so as to be in a range from approximately ten micrometers (10 μm) to approximately one hundred micrometers (100 μm).

Moreover, and as noted above by reference to FIGS. 1A and 1B, situating group III-V transistor 230 substantially over dielectrically-filled region 208 can reduce or substantially eliminate leakage under the drift region of group III-V transistor 230 corresponding to distance 238. Consequently, the standoff voltage performance of group III-V transistor 230 is also improved due to the presence of dielectrically-filled region 208.

It is further noted that, although not shown as such in FIG. 2, in some implementations analogous to the implementation shown in FIG. 1B, dielectrically-filled region 208 may extend beyond the drift region of group III-V transistor 230 corresponding to distance 238. For example, and as shown in FIG. 1B, in some implementations, dielectrically-filled region 208 may extend from top drain electrode 232, under top gate electrode 236, to approach top source electrode 234. That is to say, in some implementations, dielectrically-filled region 208 extends under group III-V body 220 between top drain electrode 232 and top source electrode 234.

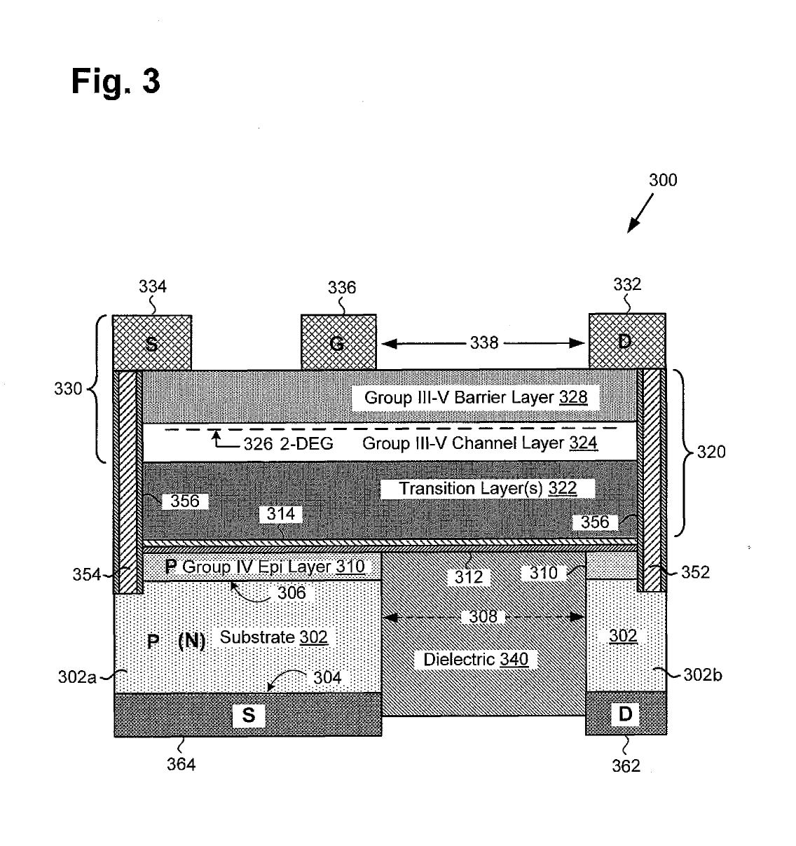

Continuing to FIG. 3, FIG. 3 shows a cross-sectional view of semiconductor structure 300 including an exemplary group III-V transistor with a voltage controlled substrate having a dielectrically-filled region, configured as a lateral HEMT having backside contacts, according to one implementation. Semiconductor structure 300 includes group III-V body 320 having transition layer(s) 322, group III-V channel layer 324, and group III-V barrier layer 328, all situated over top surface 306 of substrate 302. As shown in FIG. 3, group III-V body 320 includes group III-V transistor 330 having top drain electrode 332, top source electrode 334, top gate electrode 336, and configured to produce 2-DEG 326.

As further shown in FIG. 3, in addition to top surface 306, substrate 302 also includes bottom surface 304, source-side substrate region 302a, drain-side substrate region 302b, and dielectrically-filled region 308 substantially filled by dielectric material 340. Also shown in FIG. 3 are distance 338, source-side via 354 and drain-side via 352 each lined by insulator 356, bottom source contact 364, and bottom drain contact 362, as well as optional group IV epitaxial layer 310, strain-absorbing layer 312, and nucleation layer 314.

Substrate 302, dielectric material 340, group III-V body 320, and group III-V transistor 330 correspond respectively to substrate 102, dielectric material 140, group III-V body 120, and group III-V transistor 130, in FIGS. 1A and 1B, and may share any of the characteristics attributed to those corresponding features, above. That is to say, substrate 302 may be a highly doped silicon or other group IV substrate including dielectrically-filled region 308, dielectric material 340 may be a low-k dielectric material, and group III-V transistor 330 may take the form of a III-Nitride transistor, such as a III-Nitride or other group III-V HEMT.

In addition, group IV epitaxial layer 310, strain-absorbing layer 312, and nucleation layer 314, in FIG. 3, correspond respectively to group IV epitaxial layer 110, strain-absorbing layer 112, and nucleation layer 114, in FIGS. 1A and 1B, and may share any of the characteristics attributed to those corresponding features, above. Distance 338, in FIG. 3, corresponds to distance 238 in FIG. 2, and may share any of the characteristics attributed to that corresponding feature, above. Moreover, source-side via 354, drain-side via 352, and insulator 356 correspond respectively to source-side via 254, drain-side via 252, and insulator 256, in FIG. 2, and may share any of the characteristics attributed to those corresponding features, above.

It is noted that, in contrast to the implementations shown in FIGS. 1A, 1B, and 2, dielectric material 340, in FIG. 3, does not extend under bottom surface 304 of substrate 302. Instead, semiconductor structure 300 includes bottom source contact 364 and bottom drain contact 362 providing backside source and drain contacts for group III-V transistor 330. Thus, according to the implementation shown in FIG. 3, source-side via 354 extends through group III-V body 320 to couple top source electrode 334 of group III-V transistor 330 to source-side substrate region 302a, while source-side substrate region 302a is coupled to bottom source contact 364 situated under bottom surface 304 of substrate 302. In addition, drain-side via 352 extends through group III-V body 320 to couple top drain electrode 332 of group III-V transistor 330 to drain-side substrate region 302b, while drain-side substrate region 302b is coupled to bottom drain contact 362 situated under bottom surface 304 of substrate 302.

Semiconductor structure 300 provides substantially all of the advantages over conventional semiconductor structures described above by reference to FIGS. 1A, 1B, and 2. That is to say, group III-V transistor 330 may have a reduced R_{dson} and an increased breakdown voltage due to utilizing voltage controlled substrate 302, and further due to being situated substantially over dielectrically-filled region 308 of substrate 302. Moreover, as described by reference to FIG. 2, distance 338 corresponding to a drift region of group III-V transistor 330 may be substantially increased relative to conventional implementations. For example, distance 338 between top drain electrode 332 and top gate electrode 336 may be in a range from approximately 10 μm to approximately 100 μm.

In addition to the advantages shared with the implementations shown in FIGS. 1A, 1B, and 2, the implementation of FIG. 3 provides significant packaging flexibility as well. For example, although group III-V transistor 330 is configured as a lateral HEMT, the presence of drain-side via 352, bottom drain contact 362, and use of a highly doped substrate 302 providing drain-side substrate region 302b enable packaging solutions requiring backside contact to top drain electrode 332. Furthermore, the presence of source-side via 354, bottom source contact 364, and use of a highly doped substrate 302 providing source-side substrate region 302a enable packaging solutions requiring backside contact to top source electrode 334.

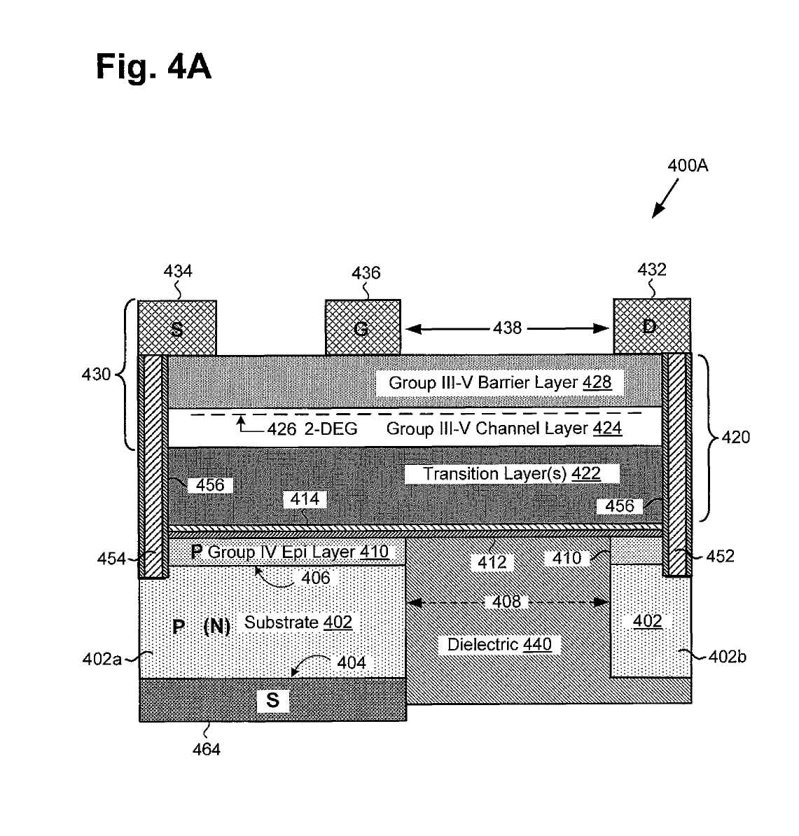

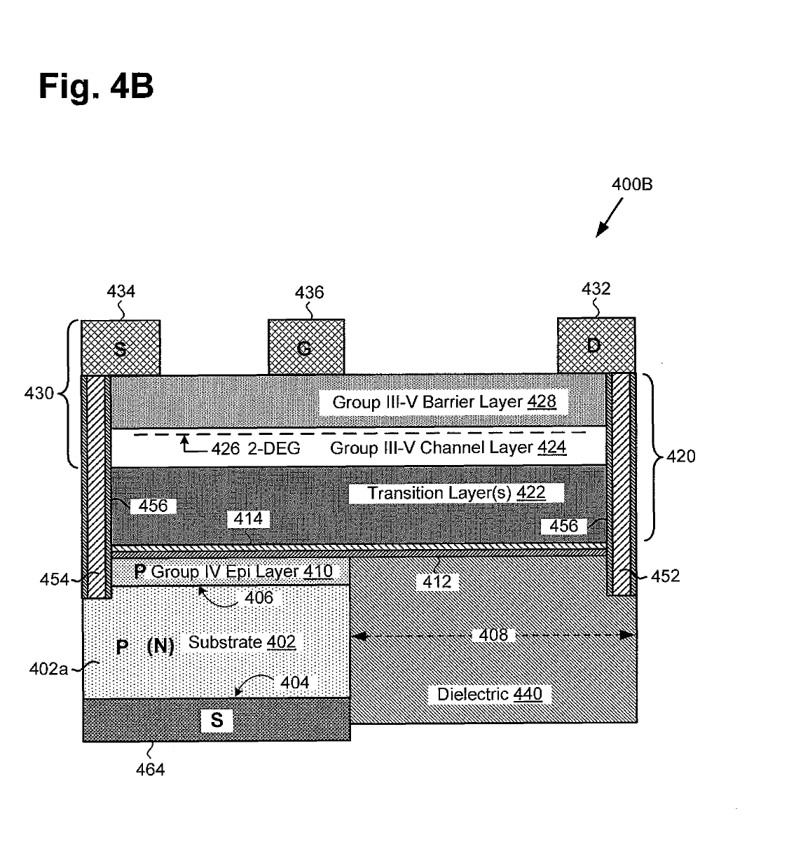

Referring to FIG. 4A, FIG. 4A shows a cross-sectional view of semiconductor structure 400A including an exemplary group III-V transistor with a voltage controlled substrate having a dielectrically-filled region, configured as a lateral HEMT having a backside contact, according to another implementation. Semiconductor structure 400A includes group III-V body 420 having transition layer(s) 422, group III-V channel layer 424, and group III-V barrier layer 428, all situated over top surface 406 of substrate 402. As shown in FIG. 4A, group III-V body 420 includes group III-V transistor 430 having top drain electrode 432, top source electrode 434, top gate electrode 436, and configured to produce 2-DEG 426.

As further shown in FIG. 4A, in addition to top surface 406, substrate 402 also includes bottom surface 404, source-side substrate region 402a, drain-side substrate region 402b, and dielectrically-filled region 408 substantially filled by dielectric material 440. Also shown in FIG. 4A are distance 438, source-side via 454 and drain-side via 452 each lined by insulator 456, and bottom source contact 464, as well as optional group IV epitaxial layer 410, strain-absorbing layer 412, and nucleation layer 414.

Substrate 402, dielectric material 440, group III-V body 420, and group III-V transistor 430 correspond respectively to substrate 102, dielectric material 140, group III-V body 120, and group III-V transistor 130, in FIGS. 1A and 1B, and may share any of the characteristics attributed to those corresponding features, above. That is to say, substrate 402 may be a highly doped silicon or other group IV substrate including dielectrically-filled region 408, dielectric material 440 may be a low-k dielectric material, and group III-V transistor 430 may take the form of a III-Nitride transistor, such as a III-Nitride or other group III-V HEMT.

In addition, group IV epitaxial layer 410, strain-absorbing layer 412, and nucleation layer 414, in FIG. 4A, correspond respectively to group IV epitaxial layer 110, strain-absorbing layer 112, and nucleation layer 114, in FIGS. 1A and 1B, and may share any of the characteristics attributed to those corresponding features, above. Distance 438, in FIG. 4A, corresponds to distance 238 in FIG. 2, and may share any of the characteristics attributed to that corresponding feature, above. Moreover, source-side via 454, drain-side via 452, and insulator 456 correspond respectively to source-side via 254, drain-side via 252, and insulator 256, in FIG. 2, and may share any of the characteristics attributed to those corresponding features, above.

It is noted that, in contrast to the implementations shown in FIGS. 1A, 1B, 2, and 3, dielectric material 440, in FIG. 4A, extends under bottom surface 404 of drain-side substrate region 402b, while bottom source contact 464 provides a backside contact for group III-V transistor 430 under bottom surface 404 of source-side substrate region 402a. Thus, according to the implementation shown in FIG. 4A, source-side via 454 extends through group III-V body 420 to couple top source electrode 434 of group III-V transistor 430 to source-side substrate region 402a, while source-side substrate region 402a is coupled to bottom source contact 464 situated under bottom surface 404 of substrate 402.

Like semiconductor structure 300, in FIG. 3, semiconductor structure 400A, in FIG. 4A, provides substantially all of the advantages over conventional semiconductor structures described above by reference to FIGS. 1A, 1B, and 2. That is to say, group III-V transistor 430 may have a reduced R_{dson} and an increased breakdown voltage due to utilizing voltage controlled substrate 402, and further due to being situated substantially over dielectrically-filled region 408 of substrate 402. Moreover, as described by reference to FIG. 2, distance 438 corresponding to a drift region of group III-V transistor 430 may be substantially increased relative to conventional implementations. For example, distance 438 between top drain electrode 432 and top gate electrode 436 may be in a range from approximately 10 μm to approximately 100 μm.

In addition to the advantages shared with the implementations shown in FIGS. 1A, 1B, and 2, the implementation of FIG. 4A, like that of FIG. 3, provides significant packaging flexibility as well. For example, although group III-V transistor 430 is configured as a lateral HEMT, the presence of source-side via 454, bottom source contact 464, and use of a highly doped substrate 402 providing source-side substrate region 402a enable packaging solutions requiring backside contact to top source electrode 434.

Moving to FIG. 4B, FIG. 4B shows a cross-sectional view of semiconductor structure 400B including an exemplary group III-V transistor with a voltage controlled substrate having a dielectrically-filled region, configured as a lateral HEMT having a backside contact, according to yet another implementation. Semiconductor structure 400B includes group III-V body 420 having transition layer(s) 422, group III-V channel layer 424, and group III-V barrier layer 428, all situated over top surface 406 of substrate 402. As shown in FIG. 4B, group III-V body 420 includes group III-V transistor 430 having top drain electrode 432, top source electrode 434, top gate electrode 436, and configured to produce 2-DEG 426.

As further shown in FIG. 4B, in addition to top surface 406, substrate 402 also includes bottom surface 404, source-side substrate region 402a, and dielectrically-filled region 408 substantially filled by dielectric material 440. Also shown in FIG. 4B are source-side via 454 and drain-side via 452 each lined by insulator 456, and bottom source contact 464, as well as optional group IV epitaxial layer 410, strain-absorbing layer 412, and nucleation layer 414.

Substrate 402, dielectric material 440, group III-V body 420, and group III-V transistor 430 correspond respectively to the features identified by reference numbers 402, 440, 420, and 430, in FIG. 4A, and may share any of the characteristics attributed to those features, above. In addition, source-side via 454, bottom source contact 464, drain-side via 452, insulator 456, group IV epitaxial layer 410, strain-absorbing layer 412, and nucleation layer 414, in FIG. 4B, correspond respectively to the features identified by reference numbers 454, 464, 452, 456, 410, 412, and 414, in FIG. 4A, and may share any of the characteristics attributed to those features, above.

It is noted that, in contrast to the implementation shown in FIG. 4A, substrate 402, in FIG. 4B, has been patterned such that drain-side substrate region 402b, in FIG. 4A, is absent from semiconductor structure 400B. In addition, dielectrically filled region 408 extends under top drain contact 432, while drain-side via 452 extends through group III-V body 420 to terminate in dielectric material 440 of dielectrically-filled region 408.

Semiconductor structure 400B provides many of the advantages over conventional semiconductor structures described above by reference to FIGS. 1A, 1B, 2, 3, and 4A. That is to say, group III-V transistor 430 may have a reduced R_{dson} and an increased breakdown voltage due to utilizing voltage controlled substrate 402, and further due to being situated substantially over dielectrically-filled region 408 of substrate 402. In addition, like the implementations shown in FIGS. 3 and 4A, semiconductor structure 400B, in FIG. 4B, provides significant packaging flexibility as well. For example, although group III-V transistor 430 is configured as a lateral HEMT, the presence of source-side via 454, bottom source contact 464, and use of a highly doped substrate 402 providing source-side substrate region 402a enable packaging solutions requiring backside contact to top source electrode 434.

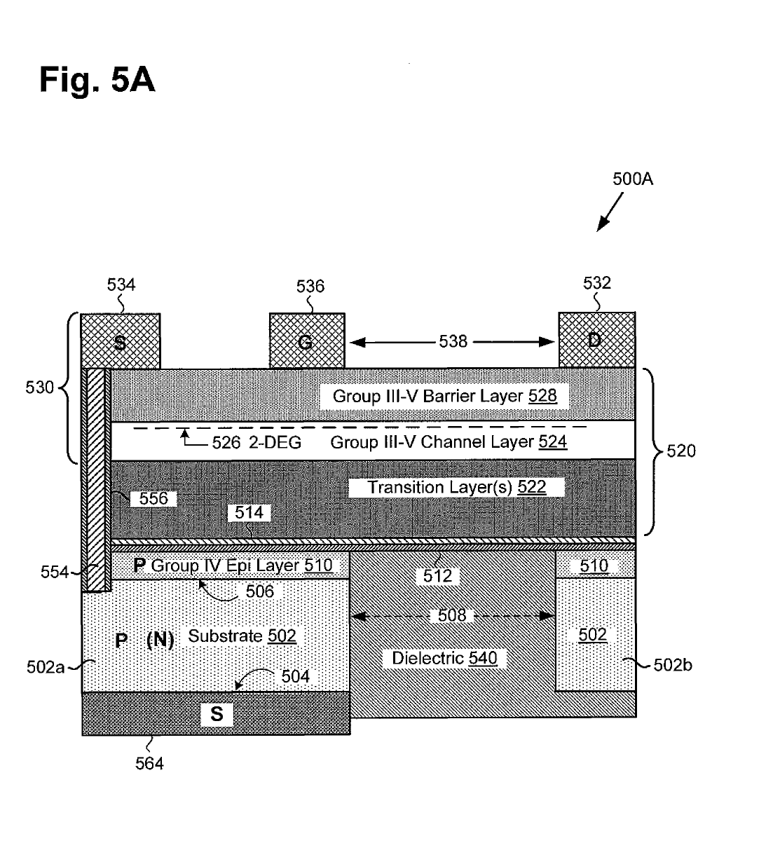

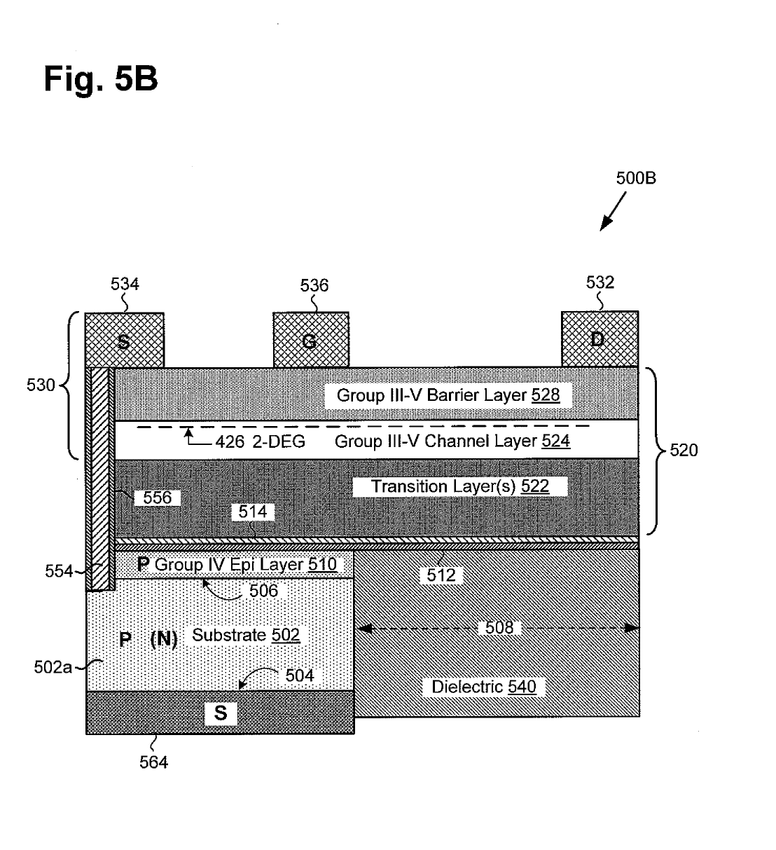

Continuing to FIG. 5A, FIG. 5A shows a cross-sectional view of semiconductor structure 500A including an exemplary group III-V transistor with a substrate having a dielectrically-filled region and a voltage controlled source-side region, configured as a lateral HEMT having a backside contact, according to one implementation. Semiconductor structure 500A includes group III-V body 520 having transition layer(s) 522, group III-V channel layer 524, and group III-V barrier layer 528, all situated over top surface 506 of substrate 502. As shown in FIG. 5A, group III-V body 520 includes group III-V transistor 530 having top drain electrode 532, top source electrode 534, top gate electrode 536, and configured to produce 2-DEG 526.

As further shown in FIG. 5A, in addition to top surface 506, substrate 502 also includes bottom surface 504, source-side substrate region 502a, drain-side substrate region 502b, and dielectrically-filled region 508 substantially filled by dielectric material 540. Also shown in FIG. 5A are distance 538, source-side via 554 lined by insulator and 556, and bottom source contact 564, as well as optional group IV epitaxial layer 510, strain-absorbing layer 512, and nucleation layer 514.

Substrate 502, dielectric material 540, group III-V body 520, and group III-V transistor 530 correspond respectively to substrate 102, dielectric material 140, group III-V body 120, and group III-V transistor 130, in FIGS. 1A and 1B, and may share any of the characteristics attributed to those corresponding features, above. That is to say, substrate 502 may be a highly doped silicon or other group IV substrate including dielectrically-filled region 508, dielectric material 540 may be a low-k dielectric material, and group III-V transistor 530 may take the form of a III-Nitride transistor, such as a III-Nitride or other group III-V HEMT.

In addition, group IV epitaxial layer 510, strain-absorbing layer 512, and nucleation layer 514, in FIG. 5A, correspond respectively to group IV epitaxial layer 110, strain-absorbing layer 112, and nucleation layer 114, in FIGS. 1A and 1B, and may share any of the characteristics attributed to those corresponding features, above. Distance 538, in FIG. 5A, corresponds to distance 238 in FIG. 2, and may share any of the characteristics attributed to that corresponding feature, above. Moreover, source-side via 554 and insulator 556 correspond respectively to source-side via 254 and insulator 256, in FIG. 2, and may share any of the characteristics attributed to those corresponding features, above.

It is noted that, in contrast to the implementations shown in FIGS. 1A, 1B, 2, and 3, dielectric material 540, in FIG. 5A, extends under bottom surface 504 of drain-side substrate region 502b, while bottom source contact 564 provides a backside contact for group III-V transistor 530 under bottom surface 504 of source-side substrate region 502a. Thus, according to the implementation shown in FIG. 5A, source-side via 554 extends through group body 520 to couple top source electrode 534 of group III-V transistor 530 to source-side substrate region 502a, while source-side substrate region 502a is coupled to bottom source contact 564 situated under bottom surface 504 of substrate 502. Moreover, semiconductor structure 500A omits a drain-side via corresponding to drain-side vias 352 and 452 shown in respective FIGS. 3 and 4A/4B.

Nevertheless, semiconductor structure 500A, in FIG. 5A, provides many of the advantages over conventional semiconductor structures described above by reference to FIGS. 1A, 1B, 2, 3, 4A, and 4B. That is to say, group transistor 530 may have a reduced R_{dson} and an increased breakdown voltage due to utilizing voltage controlled source-side substrate region 502a, and further due to being situated substantially over dielectrically-filled region 508 of substrate 502.

In addition to the advantages shared with the implementations shown in FIGS. 1A, 1B, 2, the implementation of FIG. 4A, like those of FIGS. 3, 4A, and 4B, provides significant packaging flexibility as well. For example, although group III-V transistor 530 is configured as a lateral HEMT, the presence of source-side via 554, bottom source contact 564, and use of a highly doped substrate 502 providing source-side substrate region 502a enable packaging solutions requiring backside contact to top source electrode 534.

Referring to FIG. 5B, FIG. 5B shows a cross-sectional view of semiconductor structure 500B including an exemplary group III-V transistor with a substrate having a dielectrically-filled region and a voltage controlled source-side region, configured as a lateral HEMT having a backside contact, according to another implementation. Semiconductor structure 500B includes group III-V body 520 having transition layer(s) 522, group III-V channel layer 524, and group III-V barrier layer 528, all situated over top surface 506 of substrate 502. As shown in FIG. 5B, group III-V body 520 includes group III-V transistor 530 having top drain electrode 532, top source electrode 534, top gate electrode 536, and configured to produce 2-DEG 526.

As further shown in FIG. 5B, in addition to top surface 506, substrate 502 also includes bottom surface 504, source-side substrate region 502a, and dielectrically-filled region 508 substantially filled by dielectric material 540. Also shown in FIG. 5B are source-side via 554 lined by insulator 556, and bottom source contact 564, as well as optional group IV epitaxial layer 510, strain-absorbing layer 512, and nucleation layer 514.

Substrate 502, dielectric material 540, group III-V body 520, and group III-V transistor 530 correspond respectively to the features identified by reference numbers 502, 540, 520, and 530, in FIG. 5A, and may share any of the characteristics attributed to those features, above. In addition, source-side via 554, bottom source contact 564, insulator 556, group IV epitaxial layer 510, strain-absorbing layer 512, and nucleation layer 514, in FIG. 5B, correspond respectively to the features identified by reference numbers 554, 564, 556, 510, 512, and 514, in FIG. 5A, and may share any of the characteristics attributed to those features, above.

It is noted that, in contrast to the implementation shown in FIG. 5A, substrate 502, in FIG. 5B, has been patterned such that drain-side substrate region 502b, in FIG. 5A, is absent from semiconductor structure 500B. In addition, dielectrically filled region 508 extends under top drain contact 532.

Semiconductor structure 500B provides many of the advantages over conventional semiconductor structures described above by reference to FIGS. 1A, 1B, 2, 3, 4A, 4B, and 5A. That is to say, group III-V transistor 530 may have a reduced R_{dson} and an increased breakdown voltage due to utilizing voltage controlled source-side substrate region 502a, and further due to being situated substantially over dielectrically-filled region 508 of substrate 502. In addition, like the implementations shown in FIGS. 3, 4A, 4B, and 5A, semiconductor structure 500B, in FIG. 5B, provides significant packaging flexibility as well. For example, although group III-V transistor 530 is configured as a lateral HEMT, the presence of source-side via 554, bottom source contact 564, and use of a highly doped substrate 502 providing source-side substrate region 502a enable packaging solutions requiring backside contact to top source electrode 534.

Thus, the present application discloses a group III-V transistor, such as a III-Nitride or other group III-V HEMT, with a voltage controlled substrate having a dielectrically-filled region and configured to reduce or substantially eliminate current leakage within the structure providing the transistor. In addition, according to the implementations disclosed in the present application, the group III-V transistor is situated substantially over the dielectrically-filled region. As a result, breakdown voltage of such a group III-V transistor is increased, while capacitive coupling of the transistor to its substrate is reduced, resulting in a reduction of R_{dson} during switching.

From the above description it is manifest that various techniques can be used for implementing the concepts described in the present application without departing from the scope of those concepts. Moreover, while the concepts have been described with specific reference to certain implementations, a person of ordinary skill in the art would recognize that changes can be made in form and detail without departing from the scope of those concepts. As such, the described implementations are to be considered in all respects as illustrative and not restrictive. It should also be understood that the present application is not limited to the particular implementations described herein, but many rearrangements, modifications, and substitutions are possible without departing from the scope of the present disclosure.

1. A semiconductor structure comprising:
a group IV substrate having a dielectrically-filled region;
a group III-V body situated over a top surface of said group IV substrate, said group III-V body including a group III-V transistor, said group III-V transistor including a top drain electrode, a top gate electrode, and a top source electrode;
a source-side via extending through said group III-V body to couple said top source electrode to a source-side region of said group IV substrate so as to reduce an R_{dson} of said group III-V transistor.

2. The semiconductor structure of claim 1, said group III-V transistor being situated substantially over said dielectrically-filled region so as to increase a breakdown voltage of said group III-V transistor.

3. The semiconductor structure of claim 1, wherein said dielectrically-filled region extends between said top drain electrode and said top gate electrode.

4. The semiconductor structure of claim 1, wherein said dielectrically-filled region extends between said top drain electrode and said top source electrode.

5. The semiconductor structure of claim 1, wherein said group IV substrate is a highly doped substrate.

6. The semiconductor structure of claim 1, wherein said dielectrically-filled region is filled by a low-k dielectric material.

7. The semiconductor structure of claim 1, wherein a dielectric material filling said dielectrically-filled region extends under a bottom surface of said group IV substrate.

8. The semiconductor structure of claim 1, further comprising a drain-side via extending through said group III-V body to couple said top drain electrode to a drain-side region of said group IV substrate.

9. The semiconductor structure of claim 1, wherein said group III-V transistor comprises a group III-V high electron mobility transistor (HEMT).

10. The semiconductor structure of claim 1, wherein said group III-V transistor comprises a III-Nitride transistor.

11. The semiconductor structure of claim 1, wherein said group IV substrate comprises a silicon substrate.

12. A semiconductor structure comprising:
a silicon substrate having a dielectrically-filled region;
a III-Nitride body situated over a top surface of said silicon substrate, said III-Nitride body including a III-Nitride transistor, said III-Nitride transistor including a top drain electrode, a top gate electrode, and a top source electrode;
a source-side via extending through said III-Nitride body to couple said top source electrode to a source-side region of said silicon substrate so as to reduce an R_{dson} of said III-Nitride transistor.

13. The semiconductor structure of claim 12, said III-Nitride transistor being situated substantially over said dielectrically-filled region so as to increase a breakdown voltage of said III-Nitride transistor.

14. The semiconductor structure of claim 12, wherein said dielectrically-filled region extends between said top drain electrode and said top gate electrode.

15. The semiconductor structure of claim 12, wherein said dielectrically-filled region extends between said top drain electrode and said top source electrode.

16. The semiconductor structure of claim 12, wherein said silicon substrate is a highly doped substrate.

17. The semiconductor structure of claim 12, wherein said dielectrically-filled region is filled by a low-k dielectric material.

18. The semiconductor structure of claim 12, wherein a dielectric material filling said dielectrically-filled region extends under a bottom surface of said silicon substrate.

19. The semiconductor structure of claim 12, further comprising a drain-side via extending through said III-Nitride body to couple said top drain electrode to a drain-side region of said silicon substrate.

20. The semiconductor structure of claim 12, wherein said III-Nitride transistor comprises a III-Nitride high electron mobility transistor (HEMT).
